(19) United States
(12) Patent Application Publication
(10) Pub. No.: US 2019/0181307 A1
(43) Pub. Date: Jun. 13, 2019

(54) Prepackaging Structure of Semiconductor Light Emitting Device and Semiconductor Light Emitting Device

(71) Applicant: Flory Optoelectric MAterials (Suzhou) Co., Ltd., Suzhou (CN)

(72) Inventor: Ruzhi Zhang, Suzhou (CN)

(21) Appl. No.: 16/325,989

(22) PCT Filed: Sep. 4, 2017
(86) PCT No.: PCT/CN2017/100409

§ 371 Date: Feb. 15, 2019

(30) Foreign Application Priority Data
Sep. 28, 2016 (CN) 201610859913.8
Jul. 5, 2017 (CN) 201710542460.0

(51) Int. Cl. H01L 33/50

(52) U.S. Cl. CPC H01L 33/502; H01L 2933/0091; H01L 2933/0041

(57) ABSTRACT

The present disclosure discloses a prepackaging structure of a semiconductor light emitting device, comprising: a semiconductor luminescent appliance, and a pressure sensitive phosphor film directly bonded to a luminous surface of the semiconductor luminescent appliance, wherein the pressure sensitive phosphor film comprises a base body formed by precuring an organosilicone composition, and phosphor particles are uniformly dispersed in the base body. The present disclosure further discloses a semiconductor light emitting device, comprising: a semiconductor luminescent appliance, and a fully cured body of a pressure sensitive phosphor film directly bonded to a luminous surface of the semiconductor luminescent appliance. The solution of the present disclosure can be adopted to substantially simplify packaging technology of the semiconductor luminescent appliance, reduce costs, guarantee and improve comprehensive performances of the semiconductor luminescent appliance, such as its luminous properties, including luminous uniformity, luminous efficiency, and the like, effectively improve working stability of the corresponding luminous device, and prolong its service life.

### TECHNICAL FIELD

The present disclosure relates to a packaging material applicable to the semiconductor device packaging field, and specifically to a prepackaging structure of a semiconductor light emitting device and the semiconductor light emitting device, which can be used in semiconductor appliances, such as wafer level package (WLP) LED, chip scale package (CSP) LED, quantum dot (QD) LED, laser LED, micro LED, and LED filament light bulb.

### BACKGROUND

LED (semiconductor light emitting diode) is widely used in the fields, such as lighting, and backlighting, because of its advantages, such as low power consumption, long service life, and small volume. The packaging process is a very important process in the LED manufacture process, and has very significant influence on the working performance, costs, and so on of the LED.

The existing LED packaging process mainly includes the appliance level packaging technology, wafer level package (WLP) LED technology, chip scale package (CSP) technology, and the like. These technologies have advantages respectively, but also have some defects. Therefore, the researchers are still consistently committed to improving the LED packaging technology.

The patents, such as U.S. Pat. No. 7,294,861B and US2014091346A1, have proposed a technology of packaging LED using a phosphor adhesive tape or phosphor adhesive sheet. The phosphor adhesive tape of U.S. Pat. No. 7,294,861B has a phosphor layer and an acrylate pressure sensitive adhesive layer formed from a (methyl)acrylate pressure sensitive adhesive laminated on its back. The phosphor adhesive sheet of US2014091346A1 has a phosphor layer containing a phosphor and an adhesive layer laminated on one surface in a thickness direction of the phosphor layer, wherein the adhesive layer is formed from an organosilicone pressure sensitive adhesive composition. The phosphor adhesive tape or phosphor adhesive sheet pressure is sensitively adhered to the surface of the LED by the adhesive layer. Such packaging forms have improved operation convenience and costs, compared with the traditional technology, but still have some insurmountable defects, for example: the adhesive layer will lead to leakage, it is difficult to maintain a stable adhesive force of the adhesive layer at high and low temperatures, the adhesive layer has a phenomenon of peeling under serious conditions, and therefore, the phosphor layer is likely to fall off the LED; at the same time, the adhesive layer is very likely to decompose, deteriorate, or turn yellow at a high temperature, thereby seriously affecting the luminous efficiency of LED appliances; and in addition, the adhesive layer will also go against transfer of the heat generated by the LED during working.

### SUMMARY

It is a main object of the present disclosure to provide a prepackaging structure of a semiconductor light emitting device and the semiconductor light emitting device, to overcome the defects of the existing technologies.

In order to achieve the foregoing object of the disclosure, the technical solution adopted in the disclosure includes:

an example of the present disclosure provides a prepackaging structure of a semiconductor light emitting device, comprising:

a semiconductor luminescent appliance, and

a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

Furthermore, the phosphor particles are phosphor powders having a particle size of 1-5,000 μm.

Furthermore, the phosphor particles are phosphor quantum dots having a particle size of 1-100 nm, preferably 1-20 nm. Furthermore, the phosphor film has a thickness of 10 μm-10,000 μm. Preferably, the phosphor film has a thickness of 20-500 μm.

Furthermore, a percentage of following peel strength of the phosphor film is 30% or more;

percentage of peel strength=[peel strength in an atmosphere at 75° C./peel strength in an atmosphere at 25° C.]×100

peel strength in an atmosphere at 75° C.: a peel strength at a temperature of 75° C. at the time of peeling the phosphor film from the luminous surface of the semiconductor luminescent appliance at a peel angle of 180° and at a rate of 300 mm/min; and

peel strength in an atmosphere at 25° C.: a peel strength at a temperature of 25° C. at the time of peeling the phosphor film from the luminous surface of the semiconductor luminescent appliance at a peel angle of 180° and at a rate of 300 mm/min.

An example of the present disclosure further provides a semiconductor light emitting device, comprising:

a semiconductor luminescent appliance, and

a fully cured body of a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

Furthermore, the fully cured body is integrated with the semiconductor luminescent appliance, or it can be considered that the fully cured body is firmly bonded to the luminous surface of the semiconductor luminescent appliance in such a way that it is almost non-peelable.

Furthermore, the phosphor particles are phosphor powders having a particle size of 1-50 μm.

Furthermore, the phosphor particles are phosphor quantum dots having a particle size of 1-100 nm, preferably 1-20 nm.

Furthermore, the semiconductor luminescent appliance comprises an LED.

An example of the present disclosure further provides use of a pressure sensitive phosphor film in a packaged semiconductor luminescent appliance. The pressure sensitive phosphor film is mainly formed by precuring a photocurable and/or thermocurable phosphor packaging composition, the phosphor packaging composition comprises an organosilicone composition and a phosphor material uniformly dispersed in the organosilicone composition, the phosphor material comprises phosphor powders and/or phosphor quantum dots, and the use comprises: directly adhering the phosphor film to a luminous surface of the semiconductor luminescent appliance, and enabling the phosphor film to be fully cured to form a fully cured body.

The solution of the present disclosure can be adopted to substantially simplify packaging technology of the semiconductor luminescent appliance, reduce costs, guarantee and improve luminous properties of the semiconductor luminescent appliance, such as its luminous uniformity, and luminous efficiency, effectively improve working stability of the corresponding light emitting device, and prolong its service life.

The technical solution of the present disclosure will be more specifically illustrated hereinafter in conjunction with the examples, but the examples are not used as limits to the present disclosure.

### BRIEF DESCRIPTION OF THE DRAWINGS

FIG. 1 is a structural diagram of a phosphor film package LED according to a typical example of the present disclosure; and

FIG. 2a-FIG. 2f are structural diagrams of some semiconductor light emitting devices according to some embodiments of the present disclosure.

### DETAILED DESCRIPTION OF EMBODIMENTS

In one aspect, an example of the present disclosure provides use of a phosphor film in a packaged semiconductor luminescent appliance. The phosphor film is mainly formed by precuring a photocurable and/or thermocurable phosphor packaging composition, the phosphor packaging composition comprises an organosilicone composition and a phosphor material uniformly dispersed in the organosilicone composition, the phosphor material comprises phosphor powders and/or phosphor quantum dots, and the use comprises: directly adhering the phosphor film to a luminous surface of the semiconductor luminescent appliance, and enabling the phosphor film to be fully cured.

In another aspect, an example of the present disclosure further provides a prepackaging structure of a semiconductor light emitting device, comprising:

a semiconductor luminescent appliance, and

a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

Furthermore, the phosphor particles are phosphor powders having a particle size of 1-50 μm.

Furthermore, the phosphor particles are phosphor quantum dots having a particle size of 1-100 nm, preferably 1-20 nm. Furthermore, the phosphor film has a thickness of 10 μm-10,000 μm. Preferably, the phosphor film has a thickness of 20-500 μm.

Furthermore, a percentage of following peel strength of the phosphor film is 30% or more, preferably 90% or more, and particularly preferably 100% or more;

percentage of peel strength=[peel strength in an atmosphere at 75° C./peel strength in an atmosphere at 25° C.]×100

peel strength in an atmosphere at 75° C.: a peel strength at a temperature of 75° C. at the time of peeling the phosphor film from the luminous surface of the semiconductor luminescent appliance at a peel angle of 180° and at a rate of 300 mm/min; and

peel strength in an atmosphere at 25° C.: a peel strength at a temperature of 25° C. at the time of peeling the phosphor film from the luminous surface of the semiconductor luminescent appliance at a peel angle of 180° and at a rate of 300 mm/min.

In still another aspect, an example of the present disclosure further provides a light emitting device, especially a semiconductor light emitting device, comprising:

a semiconductor luminescent appliance, and

a fully cured body of a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

Furthermore, the fully cured body is integrated with the semiconductor luminescent appliance, or it can be considered that the fully cured body is firmly bonded to the luminous surface of the semiconductor luminescent appliance in such a way that it is almost non-peelable. A semiconductor light emitting device comprises:

a semiconductor luminescent appliance, and

a fully cured body of a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

Furthermore, the fully cured body is integrated with the semiconductor luminescent appliance, or it can be considered that the fully cured body is firmly bonded to the luminous surface of the semiconductor luminescent appliance in such a way that it is almost non-peelable.

Furthermore, following thermal weight loss rate of the fully cured body is 5 wt % or less (<5 wt %); and

the thermal weight loss rate is defined as: a weight loss rate of the fully cured body after being kept at a temperature of 150° C. for 1000 hr.

Preferably, the thermal weight loss rate is 2 wt % or less.

Furthermore, the phosphor packaging composition may include:

an organosilicone composition used for semiconductor packaging; and

a phosphor material uniformly dispersed in the organosilicone composition, the phosphor material comprising phosphor powders and/or phosphor quantum dots.

Furthermore, the phosphor packaging composition is made by doping a phosphor material into an organosilicone composition while stirring at following mixing ratio.

In some embodiments, the content of the phosphor material in the phosphor packaging composition is 0.01 wt %-90 wt %, preferably 1 wt %-80 wt %, and more preferably 3 wt %-70 wt %, of a non-solvent component.

In some embodiments, a color temperature of the phosphor material is 1,000 K-30,000 K, preferably 1,800 K-20,000 K; and a color rendering index is 60-100, preferably 70-100.

In some embodiments, the phosphor powder has a particle size of 1.0-50,000 nm; preferably, the phosphor powder comprises any one or a combination of two or more of rare earth phosphor powder, rare earth garnet phosphor powder, alkaline earth metal thiogallate, alkaline earth metal sulfide, zinc sulfide type, alkaline earth metal aluminate, phosphate, borate, silicate, fluoroarsenate, fluorogermanate, rare earth sulfide, rare earth oxide, vanadate, and nitride phosphor powder, and particularly preferably, the phosphor powder is a rare earth doped yttrium aluminum garnet (YAG) phosphor powder or a Ce-doped yttrium aluminum garnet (YAG) phosphor powder.

In some embodiments, a particle size of the phosphor quantum dot is preferably 1-100 nm; preferably, a material constituting the phosphor quantum dot comprises elements in groups IIA-VIA or IIIA-VA; particularly preferably, a material of the phosphor quantum dot comprises any one or a combination of two or more of ZnSe, CdSe, and CdSe; further preferably, the material of the phosphor quantum dot is selected from the group consisting of gallium arsenide, indium phosphide, and gallium nitride; further preferably, the phosphor quantum dot has a coreshell structure; and still further preferably, the phosphor quantum dot is a quantum dot having a CdSe/ZnS coreshell structure.

In some embodiments, the content of the phosphor powder in the phosphor packaging composition is preferably 1.0 wt %-90 wt %, and more preferably 1.0 wt %-70 wt %, of a non-solvent component.

In some embodiments, the content of the phosphor quantum dot in the phosphor packaging composition is preferably 0.01 wt %-50 wt %, and more preferably 0.01 wt %-5.0 wt %, of a non-solvent component.

The organosilicone composition has, in a molecule, a main chain that is mainly composed of a siloxane bond (—Si—O—Si—) and a side chain that is bonded to silicon atoms (Si) of the main chain and is composed of an organic group, such as alkyl (for example, methyl), an aryl (for example, phenyl), or an alkoxyl (for example, methoxy). To be specific, an example of the organosilicone resin composition includes a curable type organosilicone resin, such as a dehydration condensation curable type organosilicone resin, an addition reaction curable type organosilicone resin, a peroxide curable type organosilicone resin, and a moisture curable type organosilicone resin. These resins can be used alone or in combination of two or more.

In some embodiments, the main components of the organosilicone composition include a siloxy rubber having a number average molecular weight of 3×10⁴ g/mol or more, a siloxane resin containing a vinyl functional group, a siloxane resin containing an Si—H functional group, a hydrosilylation catalyst, and an organic solvent or diluent for the formation of a homogeneous solution in combination with the components of the organosilicone composition.

In some embodiments, the siloxy rubber (also known as siloxane rubber) contains a vinyl functional group; preferably, the siloxy rubber contains 2 vinyls or more per molecule; more preferably, the siloxy rubber contains a phenyl functional group; and further preferably, the siloxy rubber contains 1 or more phenyl per molecule.

In some embodiments, the siloxane rubber is a rubber with an organosiloxane unit as a repeat unit in the main chain of a polymer, wherein the following general formula —{Si(R¹)(R²)—O-} represents an organosiloxane unit, and wherein R¹ and R² are each a monovalent organic group, or especially an alkyl such as methyl or ethyl; an aryl such as phenyl; an alkenyl such as vinyl; a cyanoalkyl such as γ-cyanopropyl; or a fluoroalkyl, such as trifluoropropyl.

In some embodiments, the siloxane rubber may be obtained by a suitable approach known in the industry, including an approach of independent preparation or purchase from the market. For example, the siloxane rubber may be obtained by referring to the documents, such as EP 0470745A2, Glossary of Chemical Terms (Van Nostr and Reinhold Company, 1976), JP2005288916, DE102004050128.9, U.S. Pat. No. 5,279,890A, JP 330084/1998, JP19981124, JP332821/1998, and CN1212265A.

More specifically, the siloxane rubber may be selected from, but is not limited to, the group consisting of dimethyl siloxane rubber, methyl phenyl siloxane rubber, methyl vinyl siloxane rubber, fluorinated alkyl methyl siloxane rubber, cyanoalkyl siloxane rubber, and the like.

Furthermore, R¹ and/or R² in the organosiloxane unit is preferably a vinyl or a phenyl.

Furthermore, the content of the siloxane rubber in the organosilicone composition may be 1 wt %-90 wt %, preferably 10 wt %-70 wt %, and particularly preferably 20 wt %-50 wt %, of a non-solvent component.

Preferably, the vinyl content in the siloxane rubber is 0.01% or more, and 70% or less of the total weight of the siloxane rubber.

More preferably, the phenyl content in the siloxane rubber is 0.01% or more, and 95% or less of the total weight of the siloxane rubber.

The number average molecular weight of the siloxy rubber is preferably 3×10⁴ g/mol-1×10⁸ g/mol, more preferably 1×10⁵ g/mol-1×10⁷ g/mol, and particularly preferably 3×10⁵ g/mol-1×10⁶ g/mol.

Furthermore, the siloxane resin containing a vinyl functional group contains 2 or more vinyls per molecule; preferably, the siloxane resin containing a vinyl functional group comprises a straight or branched chain or reticular structure; and preferably, the number average molecular weight (Mn) of the siloxane resin containing a vinyl functional group is 10⁵ g/mol or less, preferably 1×10² g/mol-1×10⁵ g/mol, and more preferably 1×10² g/mol-1×10⁴ g/mol.

More preferably, the siloxane resin containing a vinyl functional group contains 1 or more phenyl per molecule.

In some embodiments, the siloxane resin containing a vinyl functional group contains any one or a combination of more of RSiO_{3/2} unit, RR′SiO_{2/2} unit, RR′R″SiO_{1/2} unit, and SiO_{4/2} unit, wherein R, R′, and R″ are substituted or unsubstituted monovalent hydrocarbyls.

In some embodiments, the siloxane resin containing a Si—H functional group contains any one or a combination of more of RSiO_{3/2} unit, RR′SiO_{2/2} unit, RR′R″SiO_{1/2} unit, and SiO_{4/2} unit, wherein R, R′, and R″ are substituted or unsubstituted monovalent hydrocarbyls.

More specifically, in some embodiments, the structure of the siloxane resin containing a vinyl functional group is as follows:

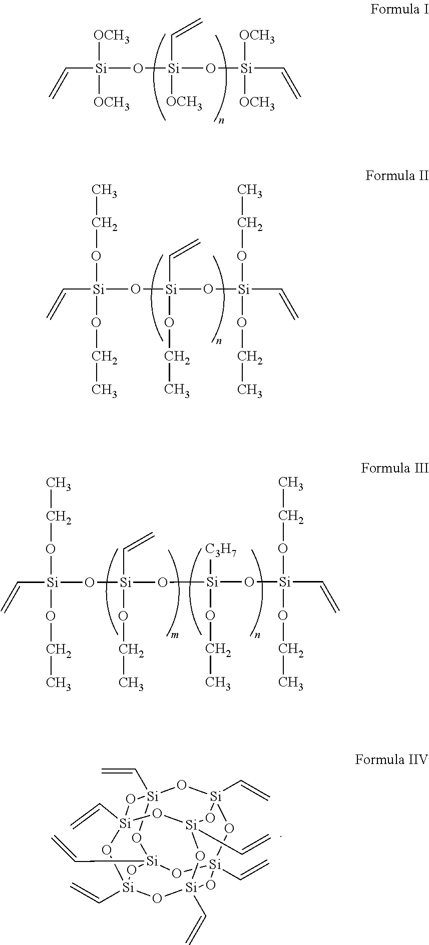

In some embodiments, the siloxane resin containing a vinyl functional group may be (R¹[OR²]SiO)ₘ—(R)³CH₂═CH—SiO)ₙ, wherein R¹, R², R³ may each be vinyl, and m and n may be 0 or a positive integer.

In some embodiments, the siloxane resin containing a vinyl functional group may be selected from vinyl-containing POSS.

Furthermore, the content of the siloxane resin containing a vinyl functional group in the organosilicone composition may be 1 wt %-90 wt %, preferably 10 wt %-70 wt %, and particularly preferably 20 wt %-50 wt %, of a non-solvent component.

In the present disclosure, the siloxane resin containing a Si—H functional group contains 2 or more Si—H per molecule; preferably, the siloxane resin containing a Si—H functional group contains a straight or branched chain or reticular structure; and preferably, the number average molecular weight of the siloxane resin containing a Si—H functional group is 10⁵ g/mol or less, preferably 10² g/mol-10⁵ g/mol, and more preferably 1×10² g/mol-1×10⁴ g/mol.

More preferably, the siloxane resin containing a Si—H functional group contains 1 or more phenyl per molecule.

In the present disclosure, in the siloxane resin containing a Si—H functional group, a silicon-bonded group rather than silicon-bonded hydrogen atoms may be optionally substituted monovalent hydrocarbyl rather than alkenyl, such as methyl, ethyl, propyl, or similar alkyl; phenyl, tolyl, xylyl, naphthyl or similar aryl; phenylmethyl, and phenylethyl or similar aralkyl; or 3-chloropropyl, 3,3,3-trifluoropropyl, or similar haloalkyl, but preferably, one molecule of the component has at least one aryl, especially phenyl, and more especially two or more phenyls. The molecular structure of the component is not specifically limited, and may have a straight-chain, branched, or partially branched straight-chain, or cyclic, or dendritic molecular structure. In some embodiments, the siloxane resin containing a Si—H functional group may be represented by following substances: an organopolysiloxane resin composed of (CH₃)₂HSiO_{1/2} and C₆H₅SiO_{3/2} units; an organopolysiloxane resin composed of (CH₃)₂HSiO_{1/2}, (CH₃)₃SiO_{1/2}, and C₆H₅SiO_{3/2} units; an organopolysiloxane resin composed of (CH₃)₂HSiO_{1/2} and SiO_{4/2} units; an organopolysiloxane resin composed of (CH₃)₂HSiO_{1/2}, (CH₃)₂SiO_{2/2} and SiO_{4/2} units, and the like.

More specifically, in some embodiments, the structure of the siloxane resin containing a Si—H functional group is as follows:

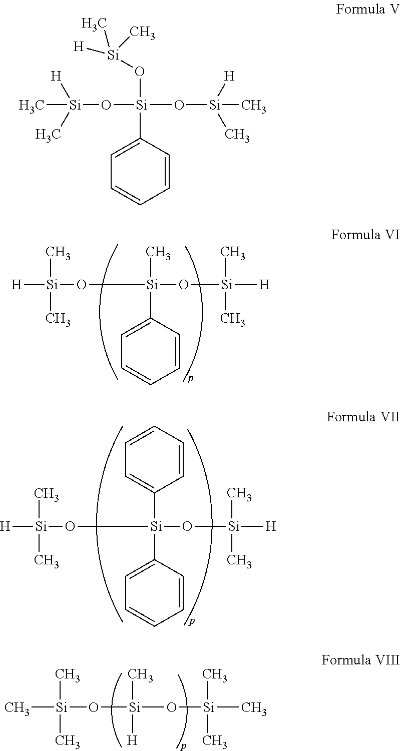

wherein p is an integer of 1 or more.

In some embodiments, the siloxane resin containing a Si—H functional group may also be selected from POSS containing a Si—H functional group.

The content of the siloxane resin containing a Si—H functional group in the organosilicone composition may be 1 wt %-90 wt %, preferably 2 wt %-50 wt %, and particularly preferably 5 wt %-30 wt %.

Furthermore, in the present disclosure, the Si—H content in the siloxane resin containing a Si—H functional group is 0.1 mol %-100 mol %, preferably 0.2 mol %-95 mol %, and particularly preferably 0.5 mol %-90 mol %.

Furthermore, in the present disclosure, a molar ratio of the Si—H in the siloxane resin containing a Si—H functional group to the vinyl in the siloxane resin containing a vinyl functional group is 0.02-50:1, preferably 0.1-10:1, and particularly preferably 0.5-5:1.

Furthermore, the selection and preparation processes of the siloxane resin containing a Si—H functional group are described in, for example, CN101151328A and CN102464887A.

Furthermore, the siloxane resins (the siloxane resin containing a vinyl functional group, the siloxane resin containing a Si—H functional group) are liquid hydrocarbons, ketones, lipids, or photoresist solvents that are soluble in benzene, toluene, xylene, heptane, and analogues, or liquid organosilicone compounds that are soluble in cyclic polydiorganosiloxane and straight chain polydiorganosiloxane having a low viscosity, and may include a monofunctional (M) unit represented by R³₃SiO_{1/2}, a difunctional (D) unit represented by R³₂SiO_{2/2}, a trifunctional (T) unit represented by R³SiO₃₁₂, and a quadrifunctional (Q) unit represented by SiO_{4/2}. R³ represents a monovalent organic group, and is a substituted or unsubstituted monovalent hydrocarbyl. The monovalent unsubstituted hydrocarbyl may be selected from, but is not limited to, the group consisting of following groups: alkyl, such as methyl, ethyl, propyl, pentyl, octyl, undecyl, and octadecyl; alkenyl, such as vinyl, allyl, butenyl, pentenyl, and hexenyl; cycloaliphatic group, such as cyclohexyl, and cyclohexenyl ethyl; alkynyl, such as ethynyl, propinyl, and butynyl; cycloalkyl, such as cyclopentyl, and cyclohexyl; and aryl, such as ethylbenzyl, naphthyl, phenyl, tolyl, xylyl, benzyl, styryl, 1-phenylethyl, and 2-phenylethyl, and may optionally be phenyl. A non-active substituent that may exist on R³ includes, but is not limited to, halo and cyano. As a substituted hydrocarbyl, the monovalent organic group may be selected from, but is not limited to, the group consisting of: haloalkyl, such as chloromethyl, 3-chloropropyl, 3,3,3-trifluoropropyl, fluoromethyl, 2-fluoropropyl, 3,3,3-trifluoropropyl, 4,4,4-trifluorobutyl, 4,4,4,3,3-pentafluorobutyl, 5,5,5,4,4,3,3-heptafluoropentyl, 6,6,6,5,5,4,4,3,3-nonafluorohexyl, 8,8,8,7,7-pentafluorooctyl, and the like. Preferably, the monovalent unsubstituted hydrocarbyl in the siloxane resin according to the present disclosure is a vinyl, and especially, the siloxane resin contains 2 or more phenyls per molecule. The selection and preparation processes of the siloxane resin according to the present disclosure are described in, for example, U.S. Pat. Nos. 6,124,407, 2,676,182, 4,774,310, and 6,124,407.

The use amount of the hydrosilylation catalyst should be enough to promote the curing of the organosilicone composition according to the present disclosure. The hydrosilylation catalysts are known in the art and are commercially available, and may be, for example, selected from, but are not limited to, following substances: a platinum group metal selected from platinum, rhodium, ruthenium, palladium, osmium or iridium metal or organometallic compound thereof, or a combination thereof. More specifically, they may be selected from the group consisting of plantinum black, reaction products of compounds such as chloroplatinic acid or chloroplatinic acid hexahydrate with monohydric alcohols, platinum bis(ethyl acetylacetate), platinum bis(acetylpyruvate), platinum dichloride, and complexes of said compounds with alkenes or low molecular weight organopolysiloxanes or platinum compounds microencapsulated in a matrix or coreshell type structure. Complexes of platinum with low molecular weight organopolysiloxanes include 1,3-diethenyl-1,1,3,3-tetramethyldisiloxane complexes with platinum. These complexes may be microencapsulated in a resin matrix. Alternatively, the catalyst may comprise 1,3-diethenyl-1,1,3,3-tetramethyldisiloxane complex with platinum. These hydrosilylation catalysts are described in, for example, CN1863875A (Paragraphs 0020-0021 in the Description), U.S. Pat. Nos. 3,159,601, 3,220,972, 3,296,291, 3,419,593, 3,516,946, 3,814,730, 3,989,668, 4,784,879, 5,036,117, 5,175,325, EP0,347,895 B, U.S. Pat. Nos. 4,766,176, and 5,017,654. And/or, at least one UV activated Pt catalyst is described in U.S. Pat. No. 8,314,200.

In some embodiments, based on the weight of the organosilicone composition, the amount of the hydrosilylation catalyst may be a platinum group metal in following range: 0.1 ppm to 10,000 ppm, optionally 1 ppm to 1,000 ppm, and more optionally 10 ppm to 100 ppm.

In the present disclosure, the solvent may be any suitable type, such as water, an organic solvent or a mixture of both, is preferably selected from an organic solvent, may be, for example, selected from, but is not limited to, the group consisting of n-hexane, toluene, chloroform, dichloromethane, ethanol, acetone, 2-butanone, 4-methyl-2-pentanone, lipid, photoresist solvents (e.g., PGME, PGMEA), and the like, and is used to combine with other materials in the composition into a liquid with good fluidity, especially a homogeneous solution.

The solvent content in the organosilicone composition may be about 10 wt %-90 wt %, preferably 20 wt %-80 wt %, and particularly preferably 30 wt %-70 wt %. Especially, the boiling point of the solvent is 60° C.-250° C. under normal pressure.

The diluent content in the organosilicone composition may be about 10 wt %-90 wt %, preferably 20 wt %-80 wt %, and particularly preferably 30 wt %-70 wt %.

In some embodiments, the diluent comprises at least one reactive diluent. Preferably, a monovinyl compound capable of participating in hydrosilylation reaction, a compound containing a Si—H functional group, or a monovinyl compound containing a Si—H functional group is used as the reactive diluent. Particularly preferably, the reactive diluent may be selected from a monovinylsilane compound and/or a monoallylsilane compound. Preferably, a viscosity of the diluent at room temperature is 100 cPs or less, particularly preferably 50 cPs or less, and more particularly preferably 10 cPs or less. By using the reactive diluent, use of organic solvents can be avoided to reduce environmental pollution, and further improve the compatibility of the components in the organosilicone composition.

More specifically, the monovinyl compound suitable for use as the diluent is described in, for example, U.S. Pat. No. 6,333,375B. For example, the reactive diluent may be selected from one or more aromatic vinyl compounds, typically including styrene, α-methylstyrene, 2-methylstyrene, methylstyrene, methylstyrene, 4-diisopropylstyrene, dimethylstyrene, 4-t-butylstyrene, 5-t-butyl-2-methylstyrene, chlorobenzene, styrene, monofluorochlorostyrene, and the like. In particular, styrene may be preferably used.

Furthermore, a polymerization monomer molecule of the monovinyl compound may also contain at least one heteroatom-containing polar group, e.g., an amino-containing vinyl monomer, a hydroxyl-containing vinyl monomer, and an oxo-containing vinyl monomer, particularly preferably the latter two. These vinyl monomers having a heteroatom-containing polar group may be used alone or in combination.

Furthermore, the amino-containing vinyl monomer is a polymerizable monomer, and at least one amino in its molecule is a primary amine (e.g., acrylamide, methacrylamide, p-aminobenzene, aminomethyl(meth)acrylic acid, aminoethyl(meth)acrylic acid, aminopropyl(meth)acrylic acid, or butyl amino(meth)acrylate), a secondary amine (see, for example, JP 130355/86A, such as anilinophenylbutadiene-monosubstituted (meth)acrylamide, e.g., N-methyl(meth)acrylamide, N-ethyl(meth)acrylamide, N-hydroxylmethacrylamide, N-(4-anilinophenyl)methacrylamide), or a tertiary amine (e.g., N,N-disubstituted aminoalkyl acrylate, N,N-dialkylaminoalkyl acrylamide, N,N-disubstituted aminoaromatic vinyl compound, and vinyl-containing pyridine compound), particularly preferably a tertiary amine. More specifically, N,N-disubstituted aminoalkyl acrylate containing acrylo or methacrylo may be selected from the group consisting of N,N-dimethylaminomethyl (meth)acrylic acid, N,N-dimethylaminoethyl (meth)acrylic acid, N,N-dimethylaminopropyl (meth)acrylic acid, N,N-dimethylaminobutyl (meth)acrylic acid, N,N-diethylaminoethyl (meth)acrylic acid, N,N-diethylaminopropyl (meth)acrylic acid, N,N-diethylaminobutyl (meth)acrylic acid, N-methyl-N-ethylaminoethyl (meth)acrylic acid, N,N-dipropylaminoethyl (meth)acrylic acid, N,N-dibutylaminoethyl (meth)acrylic acid, N,N-dibutylaminopropyl (meth)acrylic acid, N,N-dibutylaminobutyl (meth)acrylic acid, N,N-dihexylaminoethyl (meth)acrylic acid, N,N-diooctylaminoethyl (meth)acrylic acid, and acryloylmorpholine. N,N-di(meth)acrylic acid, N,N-di(meth)acrylic acid, N,N-dipropylaminoethyl (meth)acrylic acid, N,N-diooctylaminoethyl (meth)acrylic acid, and N-methyl-N-ethylaminoethyl (meth)acrylate are particularly preferred. For another example, the N,N-disubstituted aminoaromatic vinyl compound may include styrene derivatives, such as N,N-dimethylaminoethyl styrene, N,N-diethylaminoethyl styrene, N,N-dipropylaminoethyl styrene, and N,N-diooctylaminoethyl styrene. For another example, the vinyl-containing pyridine compound may include vinyl pyridine, 4-vinyl pyridine, 5-methyl-2-vinyl pyridine, 5-ethyl-2-vinyl pyridine, particularly preferably the former two.

Furthermore, the hydroxyl-containing vinyl monomer may be a polymerizable monomer containing at least one primary hydroxyl, secondary hydroxyl, or tertiary hydroxyl. These hydroxyl-containing vinyl monomers include, for example, hydroxyl-containing unsaturated carboxylic acid monomers, hydroxyl-containing vinyl ether monomers, and hydroxyl-containing vinyl ketone monomers, preferably hydroxyl-containing unsaturated carboxylic acid monomers. Examples of hydroxyl-containing unsaturated carboxylic acid monomers include acrylic acid, methacrylic acid, itaconic acid, fumaric acid, and maleic acid derivatives (e.g., esters, amides, or anhydrides). Acrylic acid and methacrylate compounds are particularly preferred. More specifically, the hydroxyl-containing vinyl monomers may include hydroxymethyl (meth)acrylic acid, hydroxypropyl (methyl) methacrylate, (meth)acrylate, hydroxypropyl (meth)acrylic acid, 2-hydroxypropyl (meth)acrylic acid, glycerol 3-phenoxy-2-hydroxypropyl (meth)acrylate, butyl (meth)acrylate, (meth)acrylic acid, 2-chloro-3-hydroxypropyl (meth)acrylic acid, hydroxyhexyl (meth)acrylate, hydroxyoctyl (meth)acrylic acid, hydroxymethyl (meth)acrylamide, 2-hydroxypropyl (meth)acrylamide, (meth)acrylamide, hydroxypropyl di(ethylene glycol)itaconic acid, di(propylene glycol)itaconate, bis(2-hydroxypropyl)bis(2-hydroxyethyl)itaconic acid, itaconic acid, bis(2-hydroxyethyl)ester, bis-(2-hydroxyethyl)maleate, methyl vinyl ether, hydroxymethyl ethenone, and allyl alcohol. Hydroxyethyl hydroxymethyl (meth)acrylate, hydroxypropyl (meth)acrylate, (meth)acrylate, hydroxypropyl (meth)acrylate, glycerol 3-phenoxy-2-hydroxypropyl (meth)acrylate, butyl (meth)acrylate, (meth)acrylate, hydroxyhexyl (meth)acrylate, hydroxypropyl (meth)acrylate, hydroxymethyl (meth)acrylamide, 2-hydroxypropyl (meth)acrylamide, and hydroxypropyl (meth)acrylamide are preferred.

Furthermore, the oxo-containing vinyl monomers may include alkoxy-containing vinyl monomers (see JP 188356/95A), such as trimethoxyvinylsilane, triethoxyvinylsilane, 6-methoxysilyl-1,2-hexene, p-trimethoxysilylstyrene, 3-(trimethoxysilyl)propyl ester, 3-(triethoxysilyl)propyl acrylate, and the like.

In some embodiments, the organosilicone compositions may further include additives, such as any one or a combination of two or more of inhibitors, micromolecular silanes (which may or may not contain vinyl or Si—H functional groups), adhesion promoters, heat or UV cured epoxy/acrylate/polyurethane/bismaleimide resins, inorganic fillers, rheology modifiers, tackifiers, wetting agents, defoamers, leveling agents, dyes, and anti-settling agents for phosphor (e.g., Shin-Etsu DM-30 and Sanwell SH series of anti-settling agents for LED phosphor).

The inhibitor, i.e., hydrosilylation reaction inhibitor, refers to a substance that can lead to poor hydrosilylation reaction, and may be, with reference to, e.g., CN1863875A (Paragraph 0025), selected from the group consisting of alkynol compound inhibitors, enyne compound inhibitors, siloxane or benzotriazole inhibitors, and other hydrosilylation reaction inhibitors. For example, the alkynol compound inhibitors may be selected from the group consisting of 2-phenyl-3-butyn-2-ol, 2-methyl-3-butyn-2-ol, 3,5-dimethyl-1-hexyn-3-ol, and the like; the enyne compounds may be selected from 3-methyl-pent-3-en-1-yne, and the like; and the siloxane may be selected from the group consisting of 1,3,5,7-tetramethyl-1,3,5,7-tetrahexenyl cyclotetrasiloxane, 1,3,5,7-tetramethyl-1,3,5,7-tetravinyl cyclotetrasiloxane, and the like. The alkynol compounds are preferable, and 2-phenyl-3-butyn-2-ol is particularly preferable.

The tackifiers or adhesion promoters may be selected from the group consisting of tetraethoxysilane, vinyltrimethoxysilane, n-butyl borate, isopropyl borate, titanium isooctanoate, zirconium isooctanoate, n-butyl titanate, isopropyl titanate, KH-171, KH-560, KH-570, and the like (see Paragraph 0026 in the Description of CN1863875A, etc.). The commercially available adhesion promoters may be, but are not limited to, JCR6101, JCR6101UP, EG6301, OE6336, JCR6175, JCR6109, Hipec4939, Hipec1-9224, OE6250, SR7010, SE9207, SE1740, SE9187L, and the like produced by Dow Corning.

The inorganic fillers may be known in the art and commercially available, and may include, for example, inorganic fillers such as silica, e.g., colloidal silica, pyrogenic silica, quartz powder, titanium oxide, glass, alumina, zinc oxide, or combinations thereof. The fillers may have an average particle size of 50 nm or less, and will not reduce the transmittance percentage by scattering or absorption.

In regard to the rheology modifiers, wetting agents, defoamers, leveling agents, dyes, and the like, their definitions are well-known in the industry, and they may be freely selected from corresponding materials frequently used in the industry.

The organosilicone composition may be made by any conventional method, for example, mixing all ingredients at a suitable temperature, e.g., at room temperature.

The viscosity of the organosilicone composition is 1,000 mPa·s-500,000 mPa·s, preferably 5,000 mPa·s-100,000 mPa·s, and particularly preferably 7,000 mPa·s-50,000 mPa·s.

The phosphor film may be formed by semi-curing (pre-curing) the phosphor packaging composition, and is preferably a flexible film.

Furthermore, the semi-curing conditions comprise: heating and ventilation conditions, temperature condition of 20° C.−200° C., preferably 80° C.−120° C., and duration of 10-100,000 s, preferably 10-8,000 s.

Furthermore, the conditions under which the phosphor film is fully cured comprise: the phosphor film is fully cured by heating or electromagnetic radiation.

Furthermore, the phosphor film may be very thin (for example, can reach about 10 μm-10,000 μm, preferably about 20-500 μm), which not only can provide efficient optical conversion efficiency, luminous uniformity, and good light color consistency, but also facilitates rapid transfer of the heat generated by the semiconductor luminescent chip during working, and thus can effectively prolong the service life of the semiconductor luminescent chip.

Furthermore, long term stability of the phosphor film can be kept in storage. To avoid external environment pollution, the phosphor film may be coated with a release material (e.g., release paper) on its surface, and the release material may be removed in use.

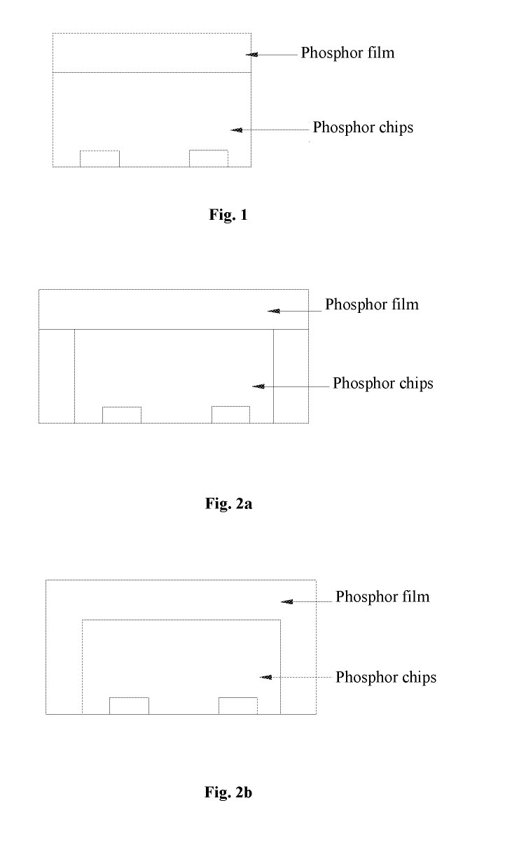

Please refer to FIG. 1, which shows a method for packaging a semiconductor luminescent appliance using the phosphor film provided by some embodiments of the present disclosure, including:

S1: forming a film: forming a film by a solution, film casting, screen/steel mesh printing, spin coating, (vacuum) extrusion, or the like of the phosphor packaging composition;

S2: initial curing: forming a pre-cured film that is non-adhesive on its surface, and can be lifted up, wherein the film is the phosphor film, and has characteristics similar to a pressure sensitive adhesive;

S3: adhering the film: covering the pre-cured film on the luminous surface of the semiconductor luminescent appliance such as LED, and adhering the phosphor film to the luminous surface of the semiconductor luminescent appliance at an elevated temperature and/or by exerting pressure;

S4: curing: curing the phosphor film adhered to the semiconductor luminescent appliance in a thermostatic (heating at an elevated temperature) environment; and

S5: post-curing treatment, e.g., cutting the cured product into smaller units.

In an alternative embodiment, the step S2) may include: removing the organic solvent from the film by radiation and/or heating and ventilation, thereby forming the pre-cured film. The heating temperature may be 20-200° C., preferably 80-120° C.; and the heating duration is 10-100,000 s, preferably 10-8,000 s.

In a preferred embodiment, the step S3) may include: at least heating the pre-cured film in the process of exerting pressure on the pre-cured film, to adhere the pre-cured film to the luminous surface of the semiconductor luminescent appliance. The exerted pressure may be 0.001 Pa-10,000 Pa, preferably 0.1 Pa-1,000 Pa; and the pressure may be exerted for a duration of 0.001-100,000 s, preferably 0.1-100 s. The heating temperature may be 0-260° C., preferably 50-200° C., and particularly preferably 80-150° C.; and the heating duration is preferably 10-100,000 s.

Of course, in step S3), other approaches may also be used to replace the heat treatment of the pre-cured film, or the pre-cured film can be treated in conjunction with the heating method. The approaches may include radiation (e.g., any one or more of far infrared, ultraviolet, visible light, microwave, and electron beams), wherein the wavelength may be 10⁻⁸-10³ m, and the duration may be 10-100,000 s.

The semiconductor luminescent appliance may be chip level LED chips, wafer level LED appliances, LD (laser devices), and so on.

In the present application, the meaning of the “packaging” is known to those skilled in the art, and may be, for example: forming a coating by curing the organosilicone composition in some areas on the surface of an article, or partially immersing one or more articles in the cured product formed from the oraganosilicone composition, or integrally encapsulating one or more articles in the cured product formed from the organosilicone composition.

Some embodiments of the present disclosure further provide light emitting devices, including a semiconductor luminescent chip, the luminous surface of which is directly coated with at least one layer of a fully cured body of the phosphor film.

For example, please refer to FIG. 1, which shows LED light emitting devices, and its packaging process may include:

preparing a phosphor film, which is covered with a release film on both side surfaces thereof;

removing the release film on one side surface of the phosphor film;

adhering the luminous surface of the LED chip to one side surface of the phosphor film at room temperature or under certain heating conditions, and exerting certain pressure by, e.g., rolling using a rubber roller, to make close adherence between them (free of bubbles);

processing shape of the phosphor film by, e.g., die cutting, to enable its shape to match the shape of the LED chip; and

removing the release film on the other side surface of the phosphor film, and embedding the LED chip to which the phosphor film is adhered into a photocuring apparatus (e.g., a UV light box) or a thermocuring apparatus (e.g., a drying oven), to fully cure the phosphor film after a period of time. The fully cured body of the phosphor film is integrated into the LED chip, and both can be hardly peeled from each other. More precisely, the fully cured body can only crack after high strength impact, and then the fragments thus formed on the surface layer will fall off, but the fully cured body will not be fully peeled from the surface of the LED chip.

The LED chip may be pre-mounted on a substrate (not shown in the figure). The LED chip is further provided with an LED side terminal to be electrically connected to the substrate side terminal of the substrate. The substrate may be formed from an insulating substrate, e.g., a laminated substrate, which is formed by laminating an insulating layer on a silicon substrate, a ceramic substrate, a polyimide resin substrate, or a metal substrate. For example, a substrate side terminal to be electrically connected to the LED side terminal of the LED and a conductor pattern connected thereto are formed on the upper surface of the substrate. The conductor pattern is formed by, for example, a conductor, such as gold, copper, silver, or nickel. LED chips can be connected to the substrate by, for example, flip chip installation or lead bonding.

Subsequently, other transparent encapsulation layer may also be set on the complex of the LED and the fully cured body of the phosphor film as needed. Such transparent encapsulation layers may be formed from transparent resins. Then, the size of such transparent encapsulation layers may also be adjusted by, e.g., grinding or cutting as needed.

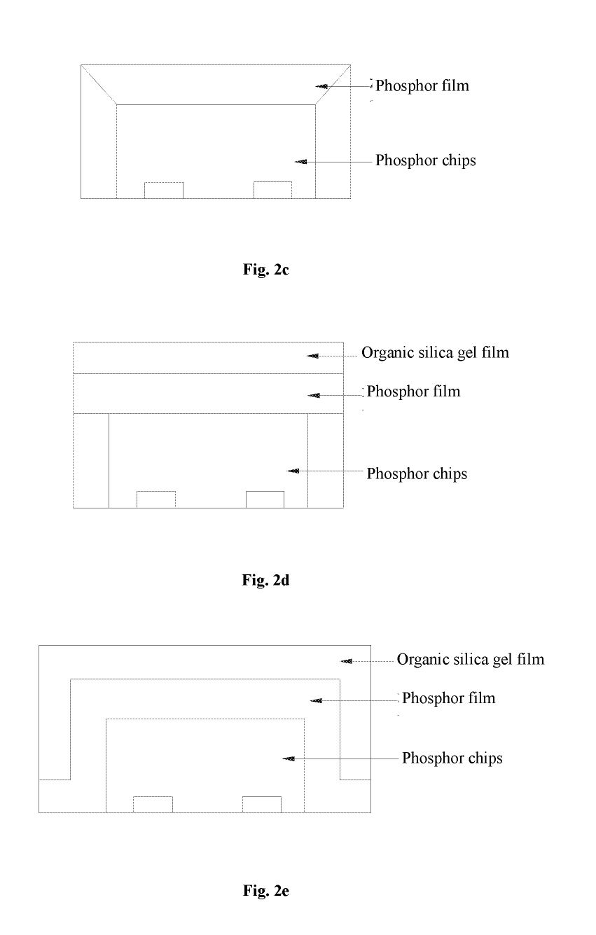

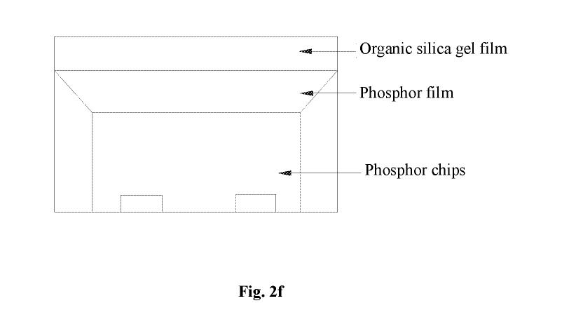

Some exemplary structures of some light emitting devices in the present disclosure are also described in FIG. 2a-FIG. 2f, wherein the structural forms shown in FIG. 2a, FIG. 2c and FIG. 2f are particularly preferred, and have better luminous uniformity.

In some more specific embodiments of the present disclosure, a manufacture process of a CSP LED packaging appliance may include:

arranging chips: arranging arrays of one or more LED chips on a substrate;

surrounding white walls, rubbing down: applying a CSP white wall adhesive on the LED chips, and then rubbing them down, to at least enable the luminous surface of each LED chip to be exposed;

adhering a film: closely adhering a phosphor film to the luminous surface of the each LED chip, and then fully curing the phosphor film; and

cutting: cutting the appliance formed in the last step, and then carrying out other post-treatment operations, to give a finished product.

The process conditions used in the process of adhering a film may include: temperature: 100-150° C., pressure: 0.003-0.015 Mpa, and duration: 1-5 min. The process conditions of fully curing a phosphor film may include: −180° C., and 2-4 hr.

In some other more specific embodiments of the present disclosure, a manufacture process of a CSP LED packaging appliance may include:

adhering chips: adhering arrays of one or more LED chips to the phosphor film;

surrounding white walls, rubbing down: applying a CSP white wall adhesive on the LED chips, and then rubbing them down, to at least enable the luminous surface of each LED chip to be exposed,

or, applying the phosphor packaging composition on other luminous surfaces of the LED chip, to form a structure of emitting light on five surfaces;

curing: fully curing the phosphor film, and the phosphor packaging composition; and

cutting: cutting the appliance formed in the last step, and then carrying out other post-treatment operations, to give a finished product.

In some more specific embodiments of the present disclosure, a manufacture process of another CSP LED packaging appliance may include:

pouring a film: closely adhering a phosphor film to a working platform (e.g., a glass working platform) to facilitate chip alignment and other operating steps, wherein a UV double-sided adhesive tape may be pre-adhered between the platform and the phosphor film to facilitate subsequent cutting and separating from the operating platform;

arranging chips: arranging arrays of one or more LED chips on the phosphor film poured onto the working platform, wherein the pressure of the mechanical arm may be adjusted according to specific circumstances until favorably adhering the chips to the phosphor film by pressure sensitivity thereof;

surrounding a white wall or phosphor powder wall: applying a CSP white wall adhesive or phosphor powder wall (i.e., a mixture of the phosphor powder and LED packaging adhesive, preferably organic silica gel) on the LED chips preferably by dispensing, and controlling its surface to stay between exposed surface of a chip electrode and chip contact surface of the chip electrode;

curing: curing the pre-cured LED packaging appliance; and

cutting: cutting the appliance formed in the last step, and then carrying out other post-treatment operations, to give a finished product.

The process conditions used in the process of arranging chips may include: temperature: 20-150° C., pressure: 0.001-0.015 Mpa, and duration: 0.01-5 min. The process conditions of fully curing the phosphor film may include: 150-180° C., and 0.5-4 hr.

The technical solution of the present disclosure is illustrated in more detail hereinafter by referring to a number of more specific examples and corresponding comparative examples. However, it is still necessary to emphasize that these examples should not be regarded as constituting any limit to the scope of protection of the present disclosure. Furthermore, all amounts, percentages, and ratios in the disclosure are by weight, unless otherwise indicated.

The phosphor film forming process involved in the following examples is as follows: pouring the phosphor packaging composition onto a flat or PET film, making a film having a certain thickness using a film former (for example, a single-sided film former of Shanghai Pushin Chemical Machinery Co., Ltd.), and obtaining a non-flowing free-standing film, i.e., the phosphor film, on the heating platform through first curing.

The phosphor packaging composition involved in the following examples can be made by referring to the widely used preparation method of the organic silica gel mixture in the industry. For example, the components of the organosilicone composition thereof may include component A (mainly including a siloxane resin containing a vinyl functional group, a platinum catalyst, an additive, and the like) and component B (mainly including a siloxane resin containing a vinyl functional group, a siloxane resin containing a S1-H functional group, an additive, and the like). The two components are mixed at a certain ratio before use, and then phosphor powder or phosphor powder combination of a corresponding content is added.

### Example 1

(1) providing an organosilicone composition containing basic components, such as vinyl siloxy rubber (component 1, SG6066, vinyldimethylsilyl terminated methyl vinyl silicone Gym, Power Chemicals Ltd, number average molecular weight of 450,000-600,000 g/mol, vinyl content of about 0.90-1.10 wt %) having a number average molecular weight of 3×10⁵ g/mol or more, a siloxane resin containing a vinyl functional group (component 2, A05-01-A, Flory Optoelectronic Materials (Suzhou) Co., Ltd.), a siloxane resin containing a S1-H functional group (component 3, A05-01-B, Flory Optoelectronic Materials (Suzhou) Co., Ltd.), a hydrosilylation catalyst (component 4, SIP6832.2, Gelest, 200 ppm), and a solvent (4-methyl-2-pentanone, 200 g). Of course, other auxiliary components may also be contained.
(2) mixing commercially available yellow phosphor powder SDY558-15 (Yantai Shield Advanced Materials Co., Ltd) in the organosilicone composition at a mass ratio of 10:1, and then fully mixing by a double planetary mixer, to form a phosphor packaging composition.
(3) coating the phosphor packaging composition on a substrate to form a film by a film former (e.g., 1 mm film former) or printing, especially by screen printing, and then heating at 100° C. (a heating platform in a ventilation cabinet) for 20 min, to give a phosphor film;
(4) arranging arrays of a plurality of LED chips (made by Nichia) on the substrate, applying a CSP white wall adhesive, and then rubbing down, to enable the luminous surface of each LED chip to be exposed;
(5) closely adhering the phosphor film to arrays of the each LED chip, and then heating at 180° C. (in a thermostatic drying oven) for 2 hr, to fully cure the phosphor film; and
(6) cutting: cutting the appliance formed in the last step by an approach known in the industry, and then carrying out other post-treatment operations, to give a finished product.

### Example 2

The example is basically identical to Example 1, except that:

The components of the phosphor packaging composition involved therein were as follows: 4 g of a vinyl siloxy rubber (SG6066, vinyldimethylsilyl terminated methyl vinyl silicone Gym, Power Chemicals Ltd, number average molecular weight of 450,000-600,000 g/mol, vinyl content of about 0.90-1.10 wt %) having a number average molecular weight of 3×10⁵ g/mol or more, 12.8 g of a siloxane resin containing a vinyl functional group (A05-01-A, Flory Optoelectronic Materials (Suzhou) Co., Ltd.), 0.35 g of a vinylmethoxysiloxane homopolymer (VMM-010, Gelest), 6.8 g of a siloxane resin containing a S1-H functional group (A05-01-B, Flory Optoelectronic Materials (Suzhou) Co., Ltd.), a hydrosilylation catalyst (SIP6832.2, Gelest, 20 ppm), 20 g of a solvent (4-methyl-2-pentanone), and 35.5 g of yellow phosphor powder SDY558-15 from Yantai Shield Advanced Materials Co., Ltd.

The pre-curing conditions in the step (3) were: 110° C. (heating platform in a ventilation cabinet) and 10 min.

The curing conditions in the step (5) were: 150° C. (heating platform in a ventilation cabinet) and 2 hr.

### Example 3

The example is basically identical to Example 1, except that:

The components of the phosphor packaging composition involved therein were as follows: 1.8 g of a vinyl siloxy rubber (SG6066, vinyldimethylsilyl terminated methyl vinyl silicone Gμm, Power Chemicals Ltd, number average molecular weight of 450,000-600,000 g/mol, vinyl content of about 0.90-1.10 wt %) having a number average molecular weight of 3×10⁵ g/mol or more, 4.6 g of a siloxane resin containing a vinyl functional group (A05-01-A, Flory Optoelectronic Materials (Suzhou) Co., Ltd.), 0.35 g of a vinylmethoxysiloxane homopolymer (VMM-010, Gelest), 4.6 g of a siloxane resin containing a S1-H functional group (A05-01-B, Flory Optoelectronic Materials (Suzhou) Co., Ltd.), a hydrosilylation catalyst (SIP6832.2, Gelest, 10 ppm), 9.0 g of a solvent (4-methyl-2-pentanone), 0.34 g of yellow phosphor powder SDY558-15, 20.1 g of green phosphor powder SDG530H, and 1.2 g of red phosphor powder SDDR630Q-2 (each of the phosphor powders was purchased from Yantai Shield Advanced Materials Co., Ltd).

Furthermore, a film was formed by a film former (400 μm gap) on a PET film in the step (3), and then initially cured to form a phosphor film.

### Example 4

The example is basically identical to Example 1, except that:

The components of the phosphor packaging composition involved therein were as follows: 3.7 g of a methyl phenyl vinyl silicone rubber (Flory Optoelectronic Materials (Suzhou) Co., Ltd., number average molecular weight of about 500,000 g/mol, phenyl content of about 30 wt %, vinyl content of about 0.35-0.40 wt %) having a number average molecular weight of 3×10⁵ g/mol or more, 7.7 g of a siloxane resin containing phenyl and vinyl functional groups (H20-01-A, Flory Optoelectronic Materials (Suzhou) Co., Ltd.), 7.7 g of a siloxane resin containing phenyl and S1-H functional groups (H20-01-B, Flory Optoelectronic Materials (Suzhou) Co., Ltd.), a hydrosilylation catalyst (SIP6832.2, Gelest, 10 ppm), 1.2 g of a solvent (4-methyl-2-pentanone), 0.48 g of yellow phosphor powder SDY558-15, 14.3 g of green phosphor powder SDG530H, and 0.86 g of red phosphor powder SDDR630Q-2 (each of the phosphor powders was purchased from Yantai Shield Advanced Materials Co., Ltd). The above components were fully mixed by a double planetary mixer, to give a mixture having a phosphor powder content of 44.9 wt %.

Furthermore, a film was formed by a film former (400 μm gap) on a PET film in the step (4), and then initially cured to form a phosphor film.

### Example 5 to Example 9

Substantially identical to Example 1, except that the formula of the organosilicone composition in the phosphor packaging composition was as shown in following table.

| | Example 5 | Example 6 | Example 7 | Example 8 | Example 9 |
|---|---|---|---|---|---|
| Component 1 | γ-cyanopropyl | Trifluoropropyl | Methylphenyl | Methylvinyl | Dimethyl |
| (MW) | siloxane rubber | siloxane rubber | siloxane rubber | siloxane rubber | siloxane rubber |
| | 4.12 × 10⁵ g/mol | 1 × 10⁸ g/mol | 1.12 × 10⁷ g/mol | 1.02 × 10⁶ g/mol | 1.05 × 10⁵ g/mol |
| Component 2 | Compound | Compound | Compound | Compound | Styryl-containing |
| (MW) | represented by | represented by | represented by | represented by | siloxane resin |
| | formula I | formula II | formula III | formula IV | 3.5 × 10³ g/mol |
| | 1.2 × 10² g/mol | 1.1 × 10³ g/mol | 1.05 × 10⁴ g/mol | 1 × 10⁵ g/mol | |
| Component 3 | Compound | Compound | Compound | Compound | Silioxane resin |
| (MW) | represented by | represented by | represented by | represented by | containing |
| | formula V | formula VI | formula VII | formula VIII | 2-fluoropropyl |
| | | | | | and Si—H |
| Component 4 | Chloroplatinic | Platinum | Platinum | Platinum bis(ethyl | Chloroplatinic |
| | acid | bis(acetylpyruvate) | dichloride | acetylacetate) | acid |
| Component 5 | PGMEA | 4-methyl-2-pentanone | Dichloromethane | Ethanol | Water |

| | | Example 5 | Example 6 | Example 7 | Example 8 | Example 9 |
|---|---|---|---|---|---|---|
| Non-solvent | Component 1 | 5% | 22% | 51% | 73% | 88% |
| component | Component 2 | 90% | 76% | 21% | 10% | 5% |
| (wt %^{★}) | Component 3 | 5% | 2% | 28% | 17% | 7% |
| | Component 4 | 1 ppm | 10 ppm | 100 ppm | 1,000 ppm | 10,000 ppm |
| Solvent | Component 5 | 50% | 30% | 70% | 90% | 10% |
| (wt %^{⋆}) | | | | | | |

^{★}shows wt % of the component 1-component 3 in the non-solvent component
^{⋆}shows wt % of the solvent in the organosilicone composition

### Example 10-Example 14

basically identical to Example 1 except that the solvent in the phosphor packaging composition was replaced with a diluent, such as α-methylstyrene, monofluorochlorostyrene, N,N-di(meth)acrylic acid, N-methyl-N-ethylaminoethyl (meth)acrylate, or hydroxymethyl (meth)acrylamide.

By referring to US2014091347A1, the typical LED package products made in the Example 1 to Example 14 (abbreviated as the products of examples), and the products of comparative examples (with reference to the products made in examples of US2014091347A1) were tested for various performances, such as the peel strength, heat loss rate, luminous intensity, and light color uniformity at high temperatures and low temperatures. The average test results were shown in the following table:

| | Whether a | Surface | Weight loss rate of | | |
|---|---|---|---|---|---|
| | phosphor film | temperature of | phosphor film after | | |
| | cured with LED | product (LED at | being maintained at | Light output | Luminous |
| | chip was peelable | full power, ° C.) | 150° C. for 1000 hr | percent (%) | light quality |
| Product of | Fully peelable | 180 | 5% or more | 100 | Poor |
| comparative | | | | | |
| example | | | | | |
| Product of | non-peelable | 170 | 2% or less | 109 | Excellent |
| example | | | | | |

It can be very obviously seen that, with the packaging approach of the present disclosure, the formed semiconductor light emitting device can have at least following characteristics: high heat resistance, non-yellowing, durability, good adhesion, excellent uniformity (color coordinate x/y), excellent light quality, high processing efficiency, and excellent yield.

It should be noted that the terms “including”, “contain” or any other variants thereof herein are intended to cover non-exclusive inclusiveness, so that the process, method, article or device including a series of elements includes not only those elements, but also other elements that are not clearly enumerated, or further includes inherent elements for this process, method, article or device.

It should be understood that the above examples only illustrate the technical concepts and features of the present disclosure, and are intended to enable those familiar with the technology to understand the contents of the disclosure and implement the disclosure accordingly, but are not intended to limit the scope of protection of the disclosure. All equivalent alterations or modifications made according to the spiritual essence of the disclosure shall fall within the scope of protection of the disclosure.

What is claimed is:

1. A prepackaging structure of a semiconductor light emitting device, comprising:
a semiconductor luminescent appliance, and
a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body.

2. The prepackaging structure according to claim 1, wherein the phosphor particles are phosphor powders having a particle size of 1-50 μm.

3. The prepackaging structure according to claim 1, wherein the phosphor particles are phosphor quantum dots having a particle size of 1.0-100 nm.

4. The prepackaging structure according to claim 1, wherein the phosphor film has a thickness of 10 μm-10,000 μm.

5. The prepackaging structure according to claim 4, wherein the phosphor film has a thickness of 20-500 μm.

6. The prepackaging structure according to claim 1, wherein a percentage of following peel strength of the phosphor film is 30% or more;
percentage of peel strength=[peel strength in an atmosphere at 75° C./peel strength in an atmosphere at 25° C.]×100
peel strength in an atmosphere at 75° C.: a peel strength at a temperature of 75° C. at the time of peeling the phosphor film from the luminous surface of the semiconductor luminescent appliance at a peel angle of 180° and at a rate of 300 mm/min; and
peel strength in an atmosphere at 25° C.: a peel strength at a temperature of 25° C. at the time of peeling the phosphor film from the luminous surface of the semiconductor luminescent appliance at a peel angle of 180° and at a rate of 300 mm/min.

7. A semiconductor light emitting device, comprising:
a semiconductor luminescent appliance, and
a fully cured body of a pressure sensitive phosphor film directly bonded to a luminous surface of the semiconductor luminescent appliance, the pressure sensitive phosphor film comprising a base body formed by precuring an organosilicone composition, phosphor particles being uniformly dispersed in the base body, the fully cured body being integrated with the semiconductor luminescent appliance.

8. The semiconductor light emitting device according to claim 7, wherein the phosphor particles are phosphor powders having a particle size of 1-50 μm.

9. The semiconductor light emitting device according to claim 7, wherein the phosphor particles are phosphor quantum dots having a particle size of 1.0-100 nm.

10. The semiconductor light emitting device according to claim 7, wherein following thermal weight loss rate of the fully cured body is 5 wt % or less;
the thermal weight loss rate is defined as: a weight loss rate of the fully cured body after being maintained at a temperature of 150° C. for 1000 hr; and
preferably, the thermal weight loss rate is 2 wt % or less.

11. The semiconductor light emitting device according to claim 7, wherein the semiconductor luminescent appliance comprises an LED.

12. Use of a pressure sensitive phosphor film in a packaged semiconductor luminescent appliance, the pressure sensitive phosphor film mainly formed by precuring a photocurable and/or thermocurable phosphor packaging composition, the phosphor packaging composition comprising an organosilicone composition and a phosphor material uniformly dispersed in the organosilicone composition, the phosphor material comprising phosphor powders and/or phosphor quantum dots, the use comprising: directly adhering the phosphor film to a luminous surface of the semiconductor luminescent appliance, and enabling the phosphor film to be fully cured to form a fully cured body.

13. The use according to claim 12, wherein the use comprises: directly covering the phosphor film on the luminous surface of the semiconductor luminescent appliance, and exerting pressure to enable the phosphor film to be closely adhered to the luminous surface of the semiconductor luminescent appliance, and then enable the phosphor film to be fully cured.

14. The use according to claim 12, wherein the phosphor particles are phosphor powders having a particle size of 1-50 μm.

15. The use according to claim 12, wherein the phosphor particles are phosphor quantum dots having a particle size of 1.0-100 nm.

16. The use according to claim 12, wherein the phosphor film has a thickness of 10 μm-10,000 preferably 20 μm-500 μm.

17. The use according to claim 12, wherein a percentage of following peel strength of the phosphor film is 30% or more;
percentage of peel strength=[peel strength in an atmosphere at 75° C./peel strength in an atmosphere at 25° C.]×100
peel strength in an atmosphere at 75° C.: a peel strength at a temperature of 75° C. at the time of peeling the phosphor film from the luminous surface of the semiconductor luminescent appliance at a peel angle of 180° and at a rate of 300 mm/min; and
peel strength in an atmosphere at 25° C.: a peel strength at a temperature of 25° C. at the time of peeling the phosphor film from the luminous surface of the semiconductor luminescent appliance at a peel angle of 180° and at a rate of 300 mm/min.

18. The use according to claim 12, wherein the fully cured body is integrated with the semiconductor luminescent appliance.

19. The use according to claim 12, wherein following thermal weight loss rate of the fully cured body is 5 wt % or less, preferably 2 wt % or less, and the thermal weight loss rate is defined as: a weight loss rate of the fully cured body after being maintained at a temperature of 150° C. for 1000 hr.

20. The use according to claim 12, wherein the semiconductor luminescent appliance comprises an LED.
